(19) United States
(12) Patent Application Publication
(10) Pub. No.: US 2022/0329037 A1
(43) Pub. Date: Oct. 13, 2022

(54) OPTICAL PULSE STRETCHER

(71) Applicant: Quantum-Si Incorporated, Guilford, CT (US)

(72) Inventors: Michael Bellos, Lebanon, CT (US); Faisal R. Ahmad, Guilford, CT (US)

(73) Assignee: Quantum-Si Incorporated, Guilford, CT (US)

(21) Appl. No.: 17/719,264

(22) Filed: Apr. 12, 2022

Related U.S. Application Data
(60) Provisional application No. 63/174,453, filed on Apr. 13, 2021.

(51) Int. Cl. H01S 5/00; G02B 27/28; G02B 27/14; H01S 5/042

(52) U.S. Cl. CPC H01S 5/0057; G02B 27/283; G02B 27/144; G02B 27/286; H01S 5/0428; H01S 5/0657

(57) ABSTRACT

Disclosed herein are aspects of an optical pulse stretcher for temporally stretching a short duration pulsed light signal to reduce its peak power, thus reducing the risk of causing damage to components that receives the pulsed light signal. Some embodiments are directed to a molecule sequencing system, in which photochemical damage caused by laser pulses having high peak power may be mitigated by the optical pulse stretcher. In one embodiment, the optical pulse stretcher comprises a polarizing beam splitter, a quarter-wave plate and a single etalon disposed in series. In another embodiments, an optical pulse stretcher splits a pulsed light signal along multiple delay lines before combining the split signals together to form a stretched light signal.

This application claims the benefit of U.S. Provisional Patent Application Ser. No. 63/174,453, filed Apr. 13, 2021, entitled “OPTICAL PULSE STRETCHER,” which is incorporated herein by reference in its entirety.

### FIELD

The present application generally relates to optical components for manipulating a light signal, and in particular to a pulse stretcher for controlling the intensity distribution of pulsed light signals from a pulsed laser.

### BACKGROUND

Optical pulses are useful in various areas of research and development as well as commercial applications. For example, optical pulses may be useful for time-domain spectroscopy, optical ranging, time-domain imaging (TDI), optical coherence tomography (OCT), fluorescent lifetime imaging (FLI), and lifetime-resolved fluorescent detection for genetic sequencing.

One application of optical pulses is in the analysis of biological or chemical samples. Such application may involve tagging samples with luminescent markers that emit light of a particular wavelength, illuminating with a light source the tagged samples, and detecting the luminescent light with a photodetector. Such techniques may involve laser light sources and systems to illuminate the tagged samples as well as complex detection optics and electronics to collect the luminescence from the tagged samples.

A pulsed laser may be used to generate a pulsed light signal that has a repetitive train of short optical pulses. Each optical pulse is a light signal that has a short time duration or pulse width in the time domain.

### SUMMARY OF THE DISCLOSURE

Disclosed herein are aspects of an optical pulse stretcher for temporally stretching a short duration pulsed light signal to reduce its peak power, thus reducing the risk of causing damage to components that receives the pulsed light signal. Some embodiments are directed to a molecule sequencing system, in which photochemical damage caused by laser pulses having high peak power may be mitigated by the optical pulse stretcher. In one embodiment, the optical pulse stretcher comprises a polarizing beam splitter, a quarter-wave plate and a single etalon disposed in series. In another embodiments, an optical pulse stretcher splits a pulsed light signal along multiple delay lines before combining the split signals together to form a stretched light signal.

In some embodiments, an optical pulse stretcher is disclosed. The optical pulse stretcher comprises an input beam splitter configured to receive a pulsed light signal along a first direction and to provide a stretched light signal along a second direction; a first beam splitter and a cavity arranged in series with the input beam splitter along the second direction. A peak power of the stretched light signal is lower than a peak power of the pulsed light signal. In some embodiments, the input beam splitter is a polarizing beam splitter and the optical pulse stretcher further comprises a quarter-wave plate disposed between the polarizing beam splitter and the first beam splitter.

In some embodiments, an optical device for stretching a pulsed light signal is disclosed. The optical device comprises a first beam splitter configured to receive the pulsed light signal and to produce a first split signal and a second split signal; a second beam splitter configured to receive the first and second split signals and to produce a third split signal and a fourth split signal; a delay component disposed in an optical path between the first and second beam splitters and configured to delay a relative timing between the first and second split signals at the second beam splitter; and a third beam splitter configured to receive the third and fourth split signals and produce a stretched light signal that is a stretched version of the pulsed light signal. A peak power of the stretched light signal is lower than a peak power of the pulsed light signal.

In some embodiments, a system is disclosed. The system comprises an integrated photonic device comprising a plurality of sample wells; a light source configured to produce a pulsed light signal; and a pulse stretcher configured to receive the pulsed light signal, and to produce a stretched light signal for exciting a plurality of samples within the plurality of sample wells. A peak power of the stretched light signal is lower than a peak power of the pulsed light signal.

### BRIEF DESCRIPTION OF THE DRAWINGS

Various aspects and embodiments of the application will be described with reference to the following figures. It should be appreciated that the figures are not necessarily drawn to scale. Items appearing in multiple figures are indicated by the same reference number in all the figures in which they appear. In the drawings:

FIG. 1 is a schematic diagram that illustrates an example of a single etalon optical pulse stretcher, in accordance with a first embodiment;

FIGS. 2A and 2B are timing diagrams illustrating temporal profiles of the input pulsed light signal 302 and the output stretched light signal of FIG. 1, respectively;

FIG. 3A is a simulated data plot of output power in a stretched light signal from a single etalon pulse stretcher as a function of time, in accordance with some embodiments;

FIG. 3B is a simulated data plot of output power in a stretched light signal from a single etalon pulse stretcher with two beam splitters as a function of time, in accordance with some embodiments;

FIGS. 3C and 3D are measured data plots of output power in light signals from a single etalon pulse stretcher with two beam splitters as a function of time, in accordance with some embodiments;

FIG. 4 is a schematic diagram that illustrates an example of an optical pulse stretcher having two loops of split optical paths, in accordance with a second embodiment;

FIG. 5 is a schematic diagram that illustrates an example of an optical pulse stretcher that is a variation of the optical pulse stretcher shown in FIG. 4, in accordance with a third embodiment;

FIG. 6 is a schematic block diagram that illustrates an example of a sequencing system with a light source that may use the optical pulse stretcher in accordance with some embodiments;

FIG. 7 is cross-sectional schematic of the sensor chip of FIG. 6.

### DETAILED DESCRIPTION

Some high power laser pulses have high peak power at the peak of the short pulses which may shorten the lifetime of components that receive the short pulses. Aspects of the present application are directed to an optical pulse stretcher that temporally stretches a short duration pulse to reduce the peak power, thus reducing the risk of causing damage to components that receives the pulsed light signal.

One application of the optical pulse stretcher disclosed herein is in single molecule sequencing, which typically involves repeated optical excitation and measurements of chemical steps on a molecular template. The inventors have recognized and appreciated that in single molecule sequencing, the cumulative possibility of early termination by a single low probability event may be a significant issue. In particular, the use of high power laser pulses provides a photophysical pathway for photochemical damage due for example to multi-photon effects. Elements in a sequencing system can simultaneously absorb two or more photons in an increasingly non-linear fashion as the laser pulse power increases. For a system that includes a resonantly absorbing species such as a dye molecule, the multi-photon absorption probability (cross-section) can become very large. Even a two-photon absorption event will create a very highly excited state molecule that has a significant potential to produce photochemical damage.

The inventors have recognized and appreciated that lowering the peak laser pulse power will significantly reduce the multi-photon effect damage pathway. Since molecular fluorescence takes place on nanosecond time scales, using a pulse stretcher to spread out a narrow laser pulse such as a pulse having ˜20 picoseconds (ps) pulse duration will not change the time resolution of a fluorescence measurement but will significantly reduce the likelihood of any multi-photon absorption.

According to some aspects, an optical pulse stretcher as disclosed herein may take a short (e.g. 20 ps) mode-locked laser pulse and spread its energy out over a fraction of one nanosecond (e.g. 100-600 ps). Meanwhile, the normal, linear single photon absorption physics and chemistry are unchanged after temporal pulse spreading as these processes are only dependent on the total, integrated number of photon seen by the sequencing system.

Some embodiments are directed to an optical pulse stretcher that comprises a polarizing beam splitter, a quarter-wave plate and a single etalon or a single cavity disposed in series such that a ring-down envelope of an input light pulse is created as a stretched light signal. Such embodiments are sometimes referred to as a single etalon pulse stretcher.

Within a single etalon pulse stretcher, a pulse from an input pulsed light signal may be first polarized by a polarizing beam splitter into a first polarized signal. The first polarized signal is converted into a circularly polarized light signal by passing through a quarter-wave plate, a portion of which is first reflected by a beam splitter. The remaining portion of the circularly polarized light signal then passes through the beam splitter and enters the cavity of the single etalon, which generates a series of ring-down pulses that are reflected back from the cavity. The ring-down pulses are combined with the initially reflected portion of circularly polarized light signal to form a stretched light signal that comprises a stretched version of the original pulse of the input pulsed light signal. The stretched light signal may have a series of pulses, each of which has a lower peak power compared to the original pulse. The stretched light signal passes through the quarter-wave plate once again to be converted back to a second linearly polarized signal that is rotated 90° from the first polarized signal, and exits the polarizing beam splitter as an output signal.

The single etalon pulse stretcher is designed to be adjustable in a number of ways. In some embodiments, a distance between the beam splitter and a mirror at an end of the cavity determines the temporal duration between subsequent the ring-down pulses. The reflectance of the beam splitter ahead of the cavity may be changed to adjust the relative amplitude, or relative peak power between subsequent pulses in the stretched light signal. In some embodiments, the beam splitter may be a first beam splitter formed of a semi-reflective surface of a plate, where the opposed surface of the plate serves as a second beam splitter. The relative ratio of reflectance of the two semi-reflective surfaces may be adjusted to create a stretched light signal envelope with low maximum peak power and fast extinction of pulses.

Using a single etalon to implement can provide several advantages. For example, because the serial arrangement of the polarizing beam splitter, the quarter-wave plate, the beam splitter and the cavity, the components are aligned to one optical axis, thus optical alignment can be simplified. Depending on the duration of the input pulse, the length of the single etalon stretcher can be made very compact. For example, to stretch a ˜1 ns pulse by ˜1 ns pulse separations, a beam splitter to mirror spacing of approximately 10 cm may be provided. To stretch a ˜10 ps pulse by ˜10 ps pulse separations, a beam splitter to mirror spacing of approximately several millimeters (mm) may be provided.

Some other embodiments are directed to an optical pulse stretcher that splits a pulsed light signal along multiple delay lines before combining the split signals together to form a stretched light signal. In some embodiment, a pulse in the pulsed light signal is split at a first beam splitter along two separate optical paths with different delays that converge in a loop fashion at a second beam splitter to generate a train of two sub-pulses, each a copy of the original pulse with different delays. The second beam splitter further splits the light signals into two separate optical paths that converge in a second loop at a third beam splitter to generate a train of four sub-pulses. The looping split optical paths can be further added to double the number of sub-pulses in the generated signal with each additional loop, before outputting the sub-pulses as a stretched light signal.

One advantage of such embodiment is that the number of sub-pulses are finite and controllable via the number of loops as opposed to the infinite number of ring-down pulses created in the single etalon stretcher. The precise control of sub-pulses allows precise control of temporal extinction of the light signal. One or more delay component may be inserted into the optical paths to adjust the relative timing of the sub-pulses.

### First Embodiment of an Optical Pulse Stretcher

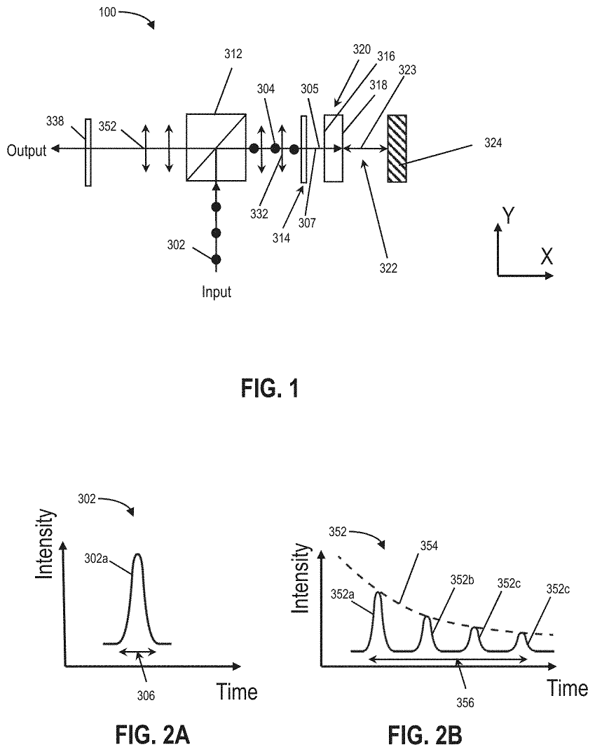

FIG. 1 is a schematic diagram that illustrates an example of a single etalon optical pulse stretcher, in accordance with a first embodiment. In FIG. 1, optical pulse stretcher 100 comprises a polarizing beam splitter 312, a quarter-wave plate 314, a plate 318 and a mirror 324 serially aligned along the X-axis. An input pulsed light signal 302 is vertically polarized (in the direction perpendicular to the XY plane), and incidents on polarizing beam splitter 312 along the Y direction. The pulsed light signal 302 is reflected as beam 304 along the X-direction, and becomes circularly polarized light signal 305 after passing through quarter-wave plate 314. A beam splitter 316 is formed on a surface of plate 320, and reflects a portion of polarized light signal 305 back along the −X direction. The remaining portion of polarized light signal 305 comprises copies of pulses in the original pulsed light signal 302, and passes beam splitter 316 into a cavity 322 formed between plate 320 and mirror 324. Light signal 305 is reflected back and forth within cavity 323 multiple times, with decaying amplitude from each reflection off plate 320 and mirror 324. As a result, cavity 322 may be referred to as a “ring-down” cavity. Light signal 307 exits cavity 322 along the −X direction, is combined with the reflected portion of the circularly polarized light signal 305, and pass through the quarter-wave plate 314 to be converted into horizontally polarized (in the Y-direction) light signal 332. Light signal 332 transmits through the polarizing beam splitter 312 as stretched light signal 352 at an output of the optical pulse stretcher 100.

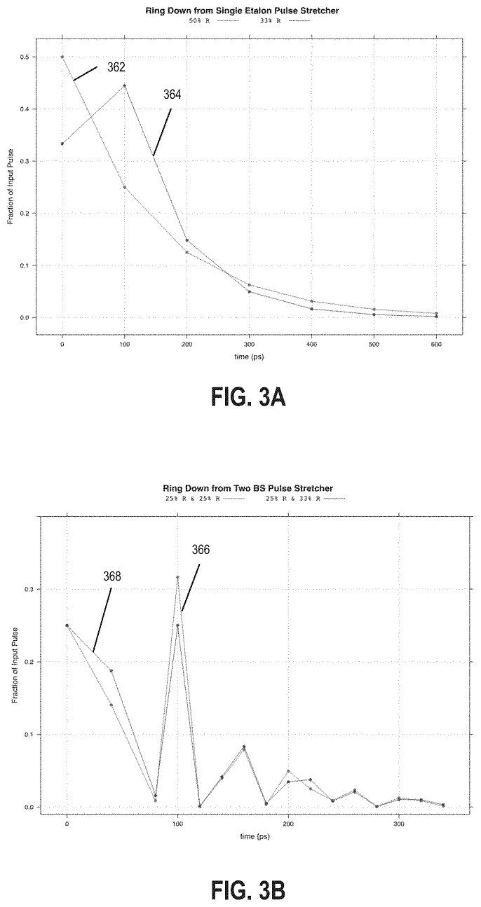

FIGS. 2A and 2B are schematic timing diagrams illustrating temporal profiles of the input pulsed light signal 302 and the output stretched light signal 352 of FIG. 1, respectively.

Pulsed light signal 302 may be a periodic pulsed signal having a repetition rate of at least 1 MHz, at least 10 MHz, at least 100 MHz, between about 10 MHz and about 500 MHz, between about 50 MHz and about 200 Hz, or any other suitable repetition rate to provide a repeated number of pulses per second. FIG. 2A illustrates a pulse 302a within one period of repetition of pulsed light signal 302, which has a short pulse duration 306.

FIG. 2B illustrates a stretched light signal 352 within the same time period as FIG. 2A, which comprises a train of sub-pulses 352a, 352b, 352c, 352d within an envelope 354. A pulse duration 356 of the stretched light signal 352 is longer than pulse duration 306. As shown in FIG. 2B, there are a multiple number of pulses per second compared to the repetition rate of the input pulsed light signal. While four sub-pulses are shown, it should be appreciated that additional ring-down pulses of smaller intensity may be present in the stretched light signal 352.

In some embodiments, pulse 302a may have a short duration 306 of less than 100 ps, for example between 10 and 50 ps, while the duration 356 of stretched light signal 352 may be more than 100 ps, for example between 100 and 600 ps. For example, in a molecular sequencing application with a pulsed laser power of 1 kilowatts (kW), if each pulse has a 10 ps pulse duration, 10 nanojoules (nJ) of energy would have been incident in the system causing high risk of photochemical damage. If each 10 ps pulse is stretched to 100 or 200 ps, the average power incident in the system can be reduced by 10 to 20 times. The inventors have recognized and appreciated that during molecule sequencing applications, measurement of accumulated fluorescence photon energy collected by photodetectors may sometimes take 1 ns or more for a given excitation, which permits the excitation pulse to be stretched from 10 ps to a longer time duration without affecting the measurement, while significantly reducing risk of photochemical damage.

In some embodiments, envelope 354 is a ring-down envelope with an intensity that drops off over time. In some embodiments, envelope 354 has an attenuation in power of at least 10 dB, at least 20 dB, at least 30 dB, or between 10 dB and 50 dB within a time duration of 500 ps. In embodiments where the optical pulse stretcher is used in a molecular sequencing application, a rapid extinction of energy in the stretched pulse light signal can give sufficient time for the system to start collect fluorescence signals. For example, the system may start the collection of fluorescence signals by about 800 ps since the beginning of the excitation, and it is desirable to extinguish energy of the ring-down sub-pulses in the stretched light signal before the start of the collection.

The first sub-pulse 352a may be a partial reflection of the light signal 305 by beam splitter 316 as shown in FIG. 1, and subsequent sub-pulses are results of the ring-down signals within cavity 322. Because optical energy of the pulse 302a is spread into multiple sub-pulses in the stretched light signal 352, each sub-pulse 352a, 352b, 352c, 352d has a lower peak intensity or peak amplitude than the original pulse 302a, such that an average power of the light signal is reduced compared to the input light signal 302, and that risk of photodamage may be reduced.

Referring back to FIG. 1, components of the single etalon stretcher 100 may be selected to effect various characteristics of the pulse stretcher, including the peak power, duration between sub-pulses and extinction of the envelope in stretched light signal 352. These components are discussed below.

Polarizing beam splitter (PBS) 312 may be implemented in any suitable way known in the field, and may reflect vertically polarized light (or s-polarization) such as light signal 302 incident along the Y-direction, and transmit horizontally polarized light (or p-polarization) such as light signal 332 along the X-direction.

Quarter-wave plate (QWP) 314 may be implemented in any suitable way known in the field, and may convert a first linear polarized light into circularly polarized light upon passing through the QWP. A circularly polarized light transmitting through the QWP again will be converted back in to a second linearly polarized light that has p-polarization, namely, rotated by 90° from the first linearly polarized light. As a result, substantially all the optical energy in the second linearly polarized light can transmit through the PBS 312 as stretched light signal 352. The QWP 314 and PBS 312 together may be considered an optical diode.

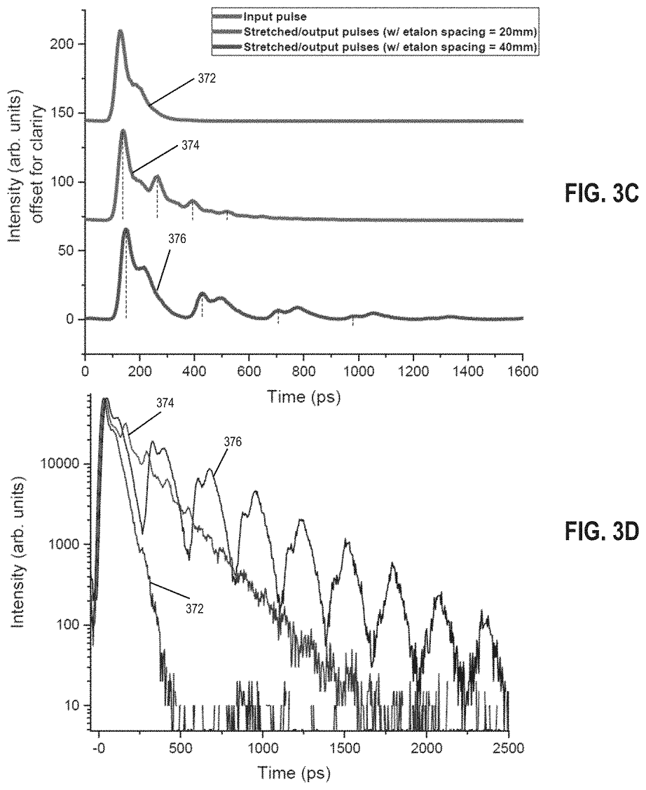

Beam splitter 316 may be a semi-reflective surface of plate 320 that faces the QWP 314, and may be formed in any suitable way known in the field. Beam splitter 316 reflects a portion of light signal 305 backwards along the −X direction, while allowing a remaining portion through to the cavity 322. As a result, adjusting the reflectance of beam splitter 316 may affect the maximum peak power and the temporary decay in the stretched light signal 352, which is illustrated in the examples in FIG. 3A.

FIG. 3A is a simulated data plot of output power in a stretched light signal from a single etalon pulse stretcher as a function of time, in accordance with some embodiments. FIG. 3A shows a curve 362 for a single etalon pulse stretcher 100 with a reflectance of 50% for beam splitter 316, and a curve 364 for the same pulse stretcher with a reflectance of 33% for beam splitter 316. A comparison of curves 362, 364 shows that switching the beam splitter reflectance from 50% to 33% makes the second sub-pulse at 100 ps having the maximum peak in curve 364, which has a fraction of about 44% of the peak power of the input pulse 302 as shown in FIG. 2A, less than the maximum peak power of about 50% in curve 362. Furthermore, curve 364 also decays faster versus time compared to curve 362. The reflectance of beam splitter 316 may be between 20% and 50%, and it was found that a 38% reflectance may produce the lowest maximum peak power of about 40% of that of the input pulse using a single etalon pulse stretcher having one beam splitter 316.

Optionally and additionally, in some embodiments two semi-reflective beam splitters may be provided in between the quarter-wave plate 316 and the mirror 324 to further reduce the maximum power in a ring-down envelope for the output light signal 352. In some embodiments, the two beam splitters may be implemented by coating the two opposing surfaces of plate 320 with semi-reflective coatings to form two beam splitters 316 and 318. Having two beam splitters on opposing surfaces of one plate may simplify optical alignments of the two plate beam splitters.

FIG. 3B is a simulated data plot of output power in a stretched light signal from a single etalon pulse stretcher with two beam splitters as a function of time, in accordance with some embodiments. In some embodiments, the first beam splitter 316 and second beam splitter 318 may each have a reflectance of between 20% and 50%. FIG. 3B shows two exemplary combination of reflectance between the two beam splitters. Curve 364 corresponds to two 25% reflectance values for both beam splitters 316, 318, while curve 368 corresponds to a 25% reflectance for beam splitter 316 followed by 33% reflectance for beam splitter 318. In the examples shown by FIG. 3B, both curves show a maximum peak power of less than 33% compared to that of the input pulse, which is an improvement compared to the single-beam splitter example illustrated in FIG. 3A. In particular, curve 368 has a maximum peak power of about 25% of that of the input pulse.

Turning back to FIG. 1, light signal that exits beam splitter 316 transmits through cavity 322 until reflected by mirror 324. Mirror 324 may be implemented by any suitable high reflectance component known in the field, such as but not limited to a 100% reflectance mirror. Beam splitter 316 and mirror 324 together form the ring-down cavity 322, with the distance between plate 320 and the mirror 324 forming a delay path 323. The distance of delay path 323 determines the duration between subsequent sub-pulses in light signal 352.

In FIG. 3B, the distance from the first beam splitter 316 to the second beam splitter 318 is τ=20 ps as measured by a time duration for light to travel from one beam splitter to the other beam splitter. The round trip time from the second beam splitter 318 to the mirror 324 and back is δ=60 ps. Because 6 relates to the time duration of pulses in the delay path 323, adjusting the ratio of τ/δ may affect the separation between sub-pulses, namely, echo separation in the stretched light signal 352 to reduce pulse pileup. The ratio τ/δ may be between ¼ and ½. In some embodiments, a ratio of τ/δ=⅓ is found to give good echo separation and little pulse pileup.

FIGS. 3C and 3D are simulated data plots of output power in light signals from a single etalon pulse stretcher with two beam splitters as a function of time, in accordance with some embodiments. FIG. 3C shows a curve 372 that is the power of a 20 ps wide input pulse in a pulsed light signal 302. Curve 374 is the power of a stretched light signal 352 using a single etalon pulse stretcher 100 with a 20 mm etalon spacing in the delay path 323. Curve 376 is the power of a stretched light signal 352 using a single etalon pulse stretcher 100 with a 40 mm etalon spacing. FIG. 3D shows the same curves 372, 374, 376 plotted in semi-log scale. As shown in FIG. 3C, four sub-pulses are highlighted by vertical lines in curve 374 to represent the effect of using a single etalon pulse stretcher to spread the optical energy in the single pulse in curve 372 into multiple, longer duration sub-pulses. A comparison between curve 374 and 376 shows that the temporal separation between the sub-pulses are increased with the increase in the etalon spacing.

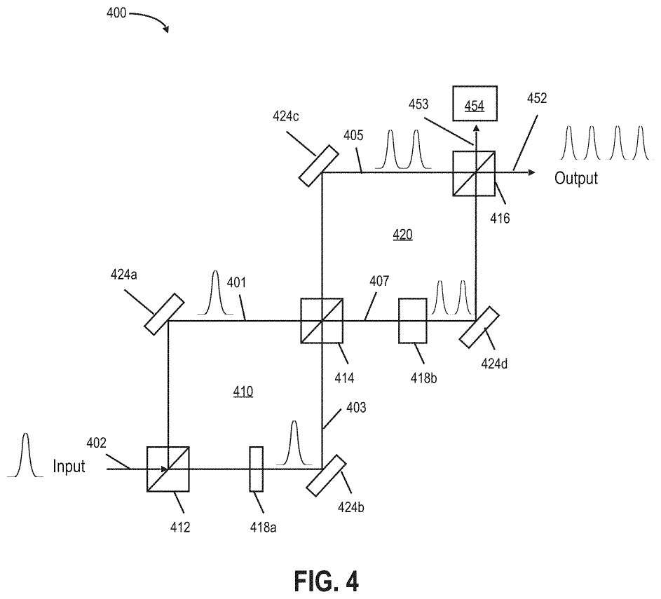

Some aspects of the present application are directed to an optical pulse stretcher that comprise multiple loops of split optical paths, an example of which is shown in FIG. 4.

### Second Embodiment of an Optical Pulse Stretcher

FIG. 4 is a schematic diagram that illustrates an example of an optical pulse stretcher having two loops of split optical paths, in accordance with a second embodiment. In FIG. 4, optical device 400 is a pulse stretcher that has a first beam splitter 412, a second beam splitter 414, and a third beam splitter 416. A first loop 410 is formed between a first optical path from the first beam splitter 412 to the second beam splitter 414 via mirror 424a, and a second optical path from the first beam splitter 412 to the second beam splitter 414 via mirror 424b. A second loop 420 is formed between a third optical path from the second beam splitter 414 to the third beam splitter 416 via mirror 424c, and a fourth optical path from the second beam splitter 414 to the third beam splitter 416 via mirror 424d.

During operation of pulse stretcher 400, an input pulsed light signal 402 is split by first beam splitter 412 into a first split signal 401 that propagates along the first optical path, and a second split signal 403 that propagates along the second optical path before the first and second split signals are combined at the second beam splitter 414. Each of the first and second split signals comprises a copy of the input pulse, and one or more delay component 418a may be disposed in one or both optical paths in the first loop 410 to adjust the relative timing when pulses in the first and second split signals 401, 403 arrive at the second beam splitter 414. As a result, light signals that exit the second beam splitter 414 may comprise two sub-pulses separated by such relative timing.

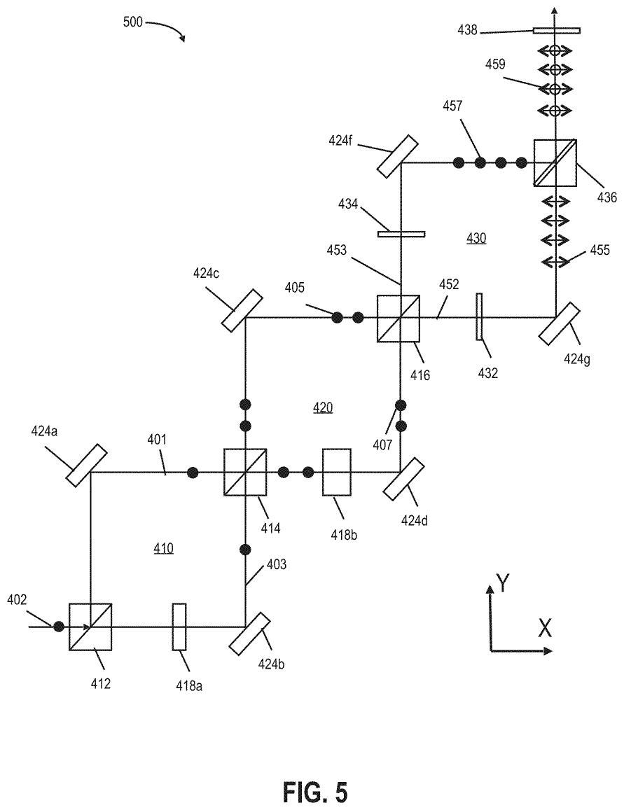

The second beam splitter 414 receives the first and second split signals 401, 403, and produces third and fourth split signals 405, 407 that each propagates along a respective optical path within loop 420 before converging at the third beam splitter 416. One or more delay component 418b may be disposed in one or both optical paths in the second loop 420 to adjust the relative timing when pulses in the third and fourth split signals 405, 407 arrive at the third beam splitter 416. As a result, light signals that exit the third beam splitter 416 comprise four sub-pulses. A stretched light signal 452 is produced from the third beam splitter 416 as a stretched version of the input pulsed light signal 402. In some embodiment, the third beam splitter 416 may also produce an output light signal 453 along a different direction from the stretched light signal 452, which may be directed to a dump point 454 are not used. However, as discussed below with respect to FIG. 5, a third loop may be introduced to recycle the optical energy in output light signal 453 such that a dump point is not needed.

Still referring to FIG. 4, the stretched light signal 452 comprises multiple sub-pulses based on a single pulse in the input pulsed light signal 402. While two loops 410, 420 are shown, aspects of the present application are not so limited as more loops can be added to further increase the number of sub-pulses in the stretched light signal, with each additional loop doubling the number of sub-pulses. One advantage of using the optical pulse stretcher 400 compared to the single etalon pulse stretcher 100 is that the number of echoes or sub-pulses are precisely controlled by the number of loops, such that distinction of the stretched light signal can be better controlled.

Delay components 418a and 418b may be implemented in any suitable way known in the field to delay a light signal. In some embodiments, delay components 418a, 418b may be a plate, for example a glass plate or glass window inserted in an optical path. A glass window can introduce a delay of approximately 5 ps per mm of thickness along the direction of the optical path, and does not require alignment or other mechanical tolerances. In one non-limiting example, glass window 418a is 6 mm thick, while glass window 418b is 12 mm thick, and the generated stretched light signal 452 has a train of four sub-pulses of equal size that are separated by about 30 ps. In some embodiments, a glass window may be tilted or rotated to fine tune the delay by fine tuning the thickness in the optical path.

### Third Embodiment of an Optical Pulse Stretcher

FIG. 5 is a schematic diagram that illustrates an example of an optical pulse stretcher that is a variation of the optical pulse stretcher shown in FIG. 4, in accordance with a third embodiment. FIG. 5 shows an optical pulse stretcher 500 that is similar to the optical pulse stretcher 400 in FIG. 4 in many aspects, with like components marked with the same reference numbers. Optical pulse stretcher 500 differs from optical pulse stretcher 400 in that a third loop 430 is added to extract all the optical powers from light signal 452 and light signal 453 without using a dump point for light signal 453.

In FIG. 5, a third loop 430 is formed between a fifth optical path from the third beam splitter 416 to the fourth beam splitter 436 via mirror 424f, and a sixth optical path from the third beam splitter 416 to the fourth beam splitter 436 via mirror 424g.

FIG. 5 shows that while beam splitters 412, 414, 416 may be non-polarizing beam splitters, the the input pulsed light signal 402 and optical signals 401, 403, 405, 407, 452 and 453 are vertically polarized (polarized in a direction perpendicular to the X-Y plane). Light signal 452 exits third beam splitter 416, passes through a half-wave plate 432, and gets rotated to become horizontally polarized light signal 455. Light signal 453 exits third beam splitter 416, passes through a zero-wave plate 434, and continues to become a vertically polarized light signal 457. Zero-wave plate 434 is used to introduce an equivalent delay as the polarization element 432 and could be a zero-wave, a full-wave or a plain isotropic (non-polarizing) element. In some embodiments where a polarizing optic is used for the zero-wave plate 434, an orientation of the zero-wave plate 434 is selected such that a light signal that leaves zero-wave plate 434 maintains its polarization. Light signals 457 and 455 are combined by a polarizing beam splitter 436 into an output stretched light signal 459 that has the same amount of optical power as the sum of light signals 455, 457. A half-wave plate 438 may be optionally provided to control the polarization of the output stretched light signal.

### Exemplary Application in Connection with a Sequencing System

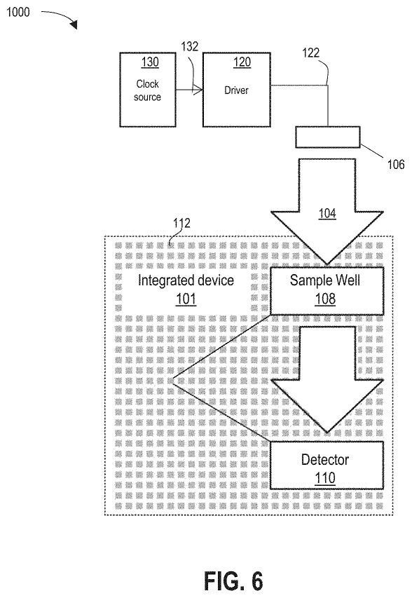

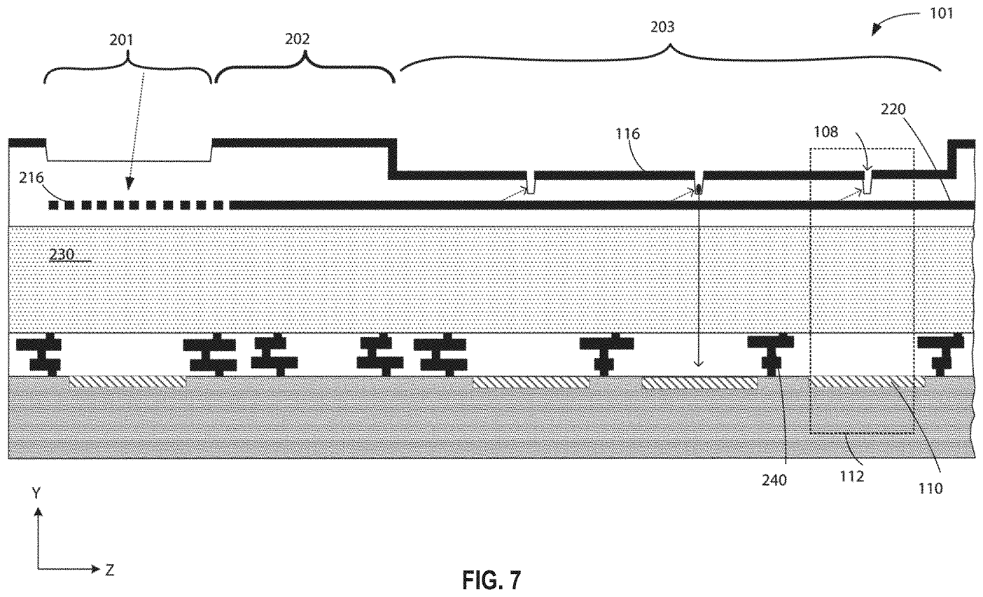

While the optical pulse stretcher disclosed herein is not limited for use in any optical applications, one exemplary application relates to a light source in a sequencing system capable of analyzing samples in parallel, including identification of single molecules, nucleic acid and/or protein sequencing. Examples of such light source and sequencing system are described below with reference to FIGS. 6 and 7.

A sequencing system may be an instrument that is compact, easy to carry, and easy to operate, allowing a physician or other provider to readily use the instrument and transport the instrument to a desired location where care may be needed. Analysis of a sample may include labeling the sample with one or more fluorescent markers, which may be used to detect the sample and/or identify single molecules of the sample (e.g., individual nucleotide identification as part of nucleic acid sequencing or). A fluorescent marker may become excited in response to illuminating the fluorescent marker with excitation light (e.g., light having a characteristic wavelength that may excite the fluorescent marker to an excited state) and, if the fluorescent marker becomes excited, emit emission light (e.g., light having a characteristic wavelength emitted by the fluorescent marker by returning to a ground state from an excited state). Detection of the emission light may allow for identification of the fluorescent marker, and thus, the sample or a molecule of the sample labeled by the fluorescent marker. According to some embodiments, the instrument may be capable of massively-parallel sample analyses and may be configured to handle tens of thousands of samples or more simultaneously.

The sequencing system may be a compact system that is capable of analyzing biological or chemical samples in parallel, including identification of single molecules and nucleic acid sequencing. The system may include an integrated device and an instrument configured to interface with the integrated device. The instrument may include one or more excitation light sources, and the integrated device may interface with the instrument such that the excitation light is delivered to the sample wells using integrated optical components (e.g., waveguides, optical couplers, optical splitters) formed as part of the integrated device. The integrated device may include an array of pixels, where each pixel includes a sample well and at least one photodetector. A surface of the integrated device may have a plurality of sample wells, where a sample well is configured to receive a sample from a sample placed on the surface of the integrated device. A sample may contain multiple samples, and in some embodiments, different types of samples. The plurality of sample wells may have a suitable size and shape such that at least a portion of the sample wells receive one sample from a sample. In some embodiments, the number of samples within a sample well may be distributed among the sample wells such that some sample wells contain one sample with others contain zero, two or more samples.

In some embodiments, a sample may be a biological and/or chemical sample for nucleic acid (e.g. DNA, RNA) sequencing or protein sequencing. For example, a sample may contain multiple single-stranded DNA templates, and individual sample wells on a surface of an integrated device may be sized and shaped to receive a sequencing template. Sequencing templates may be distributed among the sample wells of the integrated device such that at least a portion of the sample wells of the integrated device contain a sequencing template. The sample may also contain labeled nucleotides which then enter in the sample well and may allow for identification of a nucleotide as it is incorporated into a strand of DNA complementary to the single-stranded DNA template in the sample well. In such an example, the “sample” may refer to both the sequencing template and the labeled nucleotides currently being incorporated by a polymerase. In some embodiments, the sample may contain sequencing templates and labeled nucleotides may be subsequently introduced to a sample well as nucleotides are incorporated into a complementary strand within the sample well. In this manner, timing of incorporation of nucleotides may be controlled by when labeled nucleotides are introduced to the sample wells of an integrated device.

Excitation light is provided from an excitation source located separate from the pixel array of the integrated device. The excitation light is directed at least in part by elements of the integrated device towards one or more pixels to illuminate an illumination region within the sample well. A marker may then emit emission light when located within the illumination region and in response to being illuminated by excitation light. In some embodiments, one or more excitation sources are part of the instrument of the system where components of the instrument and the integrated device are configured to direct the excitation light towards one or more pixels.

Emission light emitted by a sample may then be detected by one or more photodetectors within a pixel of the integrated device. Characteristics of the detected emission light may provide an indication for identifying the marker associated with the emission light. Such characteristics may include any suitable type of characteristic, including an arrival time of photons detected by a photodetector, an amount of photons accumulated over time by a photodetector, a distribution of photons across two or more photodetectors, a wavelength value, intensity, signal pulse width, lifetime, discrimination, or any combination thereof. In some embodiments, a photodetector may have a configuration that allows for the detection of one or more timing characteristics associated with a sample's emission light (e.g., fluorescence lifetime). The photodetector may detect a distribution of photon arrival times after a pulse of excitation light propagates through the integrated device, and the distribution of arrival times may provide an indication of a timing characteristic of the sample's emission light (e.g., a proxy for fluorescence lifetime). In some embodiments, the one or more photodetectors provide an indication of the probability of emission light emitted by the marker (e.g., fluorescence intensity). In some embodiments, a plurality of photodetectors may be sized and arranged to capture a spatial distribution of the emission light. Output signals from the one or more photodetectors may then be used to distinguish a marker from among a plurality of markers, where the plurality of markers may be used to identify a sample within the sample. In some embodiments, a sample may be excited by multiple excitation energies, and emission light and/or timing characteristics of the emission light emitted by the sample in response to the multiple excitation energies may distinguish a marker from a plurality of markers.

FIG. 6 is a schematic block diagram that illustrates an example of a sequencing system 1000 with a light source that may use an optical pulse stretcher in accordance with some embodiments. The system 1000 comprises an integrated device 101 that interfaces with an instrument 180. Instrument 180 may include a light source 106 coupled to a driver circuit 120 which is coupled to a clock source 130. In some embodiments, light source 106 may be configured to generate and direct one or more pulsed light signal 104 to the integrated device. In some embodiments, an excitation light source may be external to both instrument 180 and integrated device 101, and instrument 180 may be configured to receive excitation light from the excitation source and direct excitation light to the integrated device. The integrated device may interface with the instrument using any suitable socket for receiving the integrated device and holding it in precise optical alignment with the excitation source.

The integrated device 101 has a plurality of pixels 112, where at least a portion of pixels may perform independent analysis of a sample. Such pixels 112 may be referred to as “passive source pixels” since a pixel receives excitation light from light source 106 separate from the pixel, where excitation light from the source excites some or all of the pixels 112.

A pixel 112 has a sample well 108, also referred to as a reaction chamber, that is configured to receive a sample and a photodetector 110 for detecting emission light emitted by the sample in response to illuminating the sample with excitation light provided by the light source 106. In some embodiments, sample well 108 may retain the sample in proximity to a surface of integrated device 101, which may ease delivery of excitation light to the sample and detection of emission light from the sample.

Optical elements for coupling excitation light from light source 106 to integrated device 101 and guiding pulsed light signals 104 to the sample well 108 may be located both on integrated device 101 and external to the integrated device 101. Source-to-well optical elements may comprise one or more grating couplers located on integrated device 101 to couple excitation light to the integrated device and waveguides to deliver excitation light from instrument 104 to sample wells in pixels 112. One or more optical splitter elements may be positioned between a grating coupler and the waveguides. The optical splitter may couple excitation light from the grating coupler and deliver excitation light to at least one of the waveguides. In some embodiments, the optical splitter may have a configuration that allows for delivery of excitation light to be substantially uniform across all the waveguides such that each of the waveguides receives a substantially similar amount of excitation light. Such embodiments may improve performance of the integrated device by improving the uniformity of excitation light received by sample wells of the integrated device. Some examples of source-to-well optical elements are described in U.S. patent application Ser. No. 16/733,296, filed on Jan. 3, 2020, titled “OPTICAL WAVEGUIDES AND COUPLERS FOR DELIVERING LIGHT TO AN ARRAY OF PHOTONIC ELEMENTS,” the entirety of which is herein incorporated by reference herein in its entirety. Examples of suitable components, for coupling excitation light to a sample well and/or directing emission light to a photodetector, to include in an integrated device are described in U.S. patent application Ser. No. 14/821,688, filed Aug. 7, 2015, titled “INTEGRATED DEVICE FOR PROBING, DETECTING AND ANALYZING MOLECULES,” and U.S. patent application Ser. No. 14/543,865, filed Nov. 17, 2014, titled “INTEGRATED DEVICE WITH EXTERNAL LIGHT SOURCE FOR PROBING, DETECTING, AND ANALYZING MOLECULES,” each of which is incorporated herein by reference in its entirety.

Sample well 108, a portion of the excitation source-to-well optics, and the sample well-to-photodetector optics are located on integrated device 101, sometimes also referred to as a chip or sensor chip. Light source 106 and a portion of the source-to-well components are located off the chip 101. In some embodiments, a single component may play a role in both coupling excitation light to sample well 108 and delivering emission light from sample well 108 to photodetector 110. Pixel 112 is associated with its own individual sample well 108 and at least one photodetector 110. The plurality of pixels of integrated device 101 may be arranged to have any suitable shape, size, and/or dimensions. Integrated device 101 may have any suitable number of pixels or sample wells. In some embodiments, integrated device 101 may have an array of 1 million, 8 million, 32 million, between 1 and 10 million, between 10 and 50 million, or any suitable number of sample wells excited by light signals 104 generated by light source 106.

In some embodiments, the pixels may be arranged in an array of 512 pixels by 512 pixels. Integrated device 101 may interface with instrument 180 in any suitable manner. In some embodiments, instrument 180 may have an interface that detachably couples to integrated device 101 such that a user may attach integrated device 101 to instrument 180 for use of integrated device 101 to analyze a sample and remove integrated device 101 from instrument 180 to allow for another integrated device to be attached. The interface of instrument 180 may position integrated device 101 to couple with circuitry of instrument 180 to allow for readout signals from one or more photodetectors to be transmitted to instrument 180. Integrated device 101 and instrument 180 may include multi-channel, high-speed communication links for handling data associated with large pixel arrays (e.g., more than 10,000 pixels).

### Exemplary Light Source for Use with a Sequencing System

In FIG. 6, light source 106 may comprise a pulsed laser that can provide a light signal with a repetitive train of ultrashort pulses, and an optical pulse stretcher as will be described in detail below to stretch the ultrashort pulses from the pulsed laser to be output as pulsed light signal 104. For example, light source 106 may be capable to provide sub-100-picosecond full-width-half-maximum (FWHM) pulses at selected wavelengths and at average optical powers as high as 3.5 Watts (W). Any suitable pulsed laser source may be used in light source 106. In some embodiments, light source 106 may be a compact, ultrashort-pulsed lasing system that is suitable for mobile applications. The lasing system can be configured to provide a repetition rate of optical pulses between about 50 MHz and about 200 MHz, which is well suited for massively parallel data acquisition. In some embodiments, an area occupied by a mode-locked laser module and its optics can be about the size of an A4 sheet of paper with a thickness of about 40 mm or less. A volume occupied by the module may be at most 0.07 ft³, which is nearly a factor of 10 reduction in volume occupied by conventional ultrashort-pulsed lasers that cannot deliver as much optical power. Because the laser has a compact slab form factor, it can be readily incorporated into an instrument as a replaceable module, e.g., a module to swap in or out as one might add or exchange boards on a personal computer.

To avoid interference of the excitation energy with subsequent signal collection, the excitation pulse may need to reduce in intensity by at least 50 dB within about 100 ps from the peak of the excitation pulse. In some implementations, the excitation pulse may need to reduce in intensity by at least 80 dB within about 100 ps from the peak of the excitation pulse. Mode-locked lasers can provide such rapid turn-off characteristics. In some implementations, light source 106 may be a compact mode-locked laser that can provides pulses at repetition rates between 50 MHz and 200 MHz, at wavelengths between 500 nm and 650 nm, at average powers between 250 mW and 1 W, in a compact module (e.g., occupying a volume of less than 0.1 ft³). Examples of a compact mode-locked laser are described in U.S. Pat. No. 10,283,928, issued May 7, 2019, titled “COMPACT MODE-LOCKED LASER MODULE,” the entirety of which is herein incorporated by reference herein in its entirety. In other embodiments, driver circuit 120 and/or clock source 130 may also be provided independently from such an instrument.

Still referring to FIG. 6, driver circuit 120 receives a master clock signal 132 from clock source 130, and generates drive signals 122 to synchronize generation of the pulsed light signal 104 by light source 106. In some embodiments, timings of each drive signal may be adjustable, for example by one or more programmable delay lines or any suitable delay circuits within the driver circuit 120 that can generate a corresponding delayed timing signal that is a delayed version of the master clock signal 132 and used to set the timing of each drive signal 122. The amount of programmable delays applied to each drive signal may be selected to synchronize excitation of samples in the chip 101 with pulsed light signals produced by light source 106. For example, the delays may be adjusted to compensate for the variance of propagation delays in optical paths for different laser diodes to excite sample wells at the same timing on the chip to reduce or eliminate skew across the array of laser diodes. In some embodiments, delays applied to each drive signal may be selected such that the excitation at sample wells on the chip by different laser diodes is synchronized with a timing of time-domain sensing operations on the chip. In some embodiments, the amount of programmable delays may be determined during a calibration procedure that iteratively adjusts one or more delay amounts in the driver circuit until a timing relationship such as a measured amount of skew is within a predefined threshold.

Driver circuit 120 and clock source 130 may be implemented in any suitable ways. In some embodiments, driver circuit 120 may comprise an integrated circuit disposed in a semiconductor substrate. In some embodiments, driver circuit 120 may comprise one or more printed circuit boards (PCBs). In some embodiments, driver circuit 120 may comprise a plurality of driver units corresponding to each laser diode within the light source. Driver circuit 120 may copy the received master clock signal 132, apply a programmable delay, and generate a delayed clock signal as timing for each of the plurality of driver units. In some embodiments, the clock source 130 and driver circuit 120 may be part of an instrument that interface with the integrated device for analyzing readout signals from one or more photodetectors in the pixels on the chip, and the clock signal 132 may be synchronized with a clock within such an instrument for analysis of the readout signals. For example, a signal derived from sensing the optical pulses can be used to generate an electronic clock signal that can be used to synchronize instrument electronics (e.g., data acquisition cycles) with the timing of optical pulses produced by the light source. Examples of an instrument are described in U.S. patent application Ser. No. 16/733,296, filed on Jan. 3, 2020, titled “OPTICAL WAVEGUIDES AND COUPLERS FOR DELIVERING LIGHT TO AN ARRAY OF PHOTONIC ELEMENTS,” the entirety of which is herein incorporated by reference herein in its entirety. In other embodiments, driver circuit 120 and/or clock source 130 may also be provided independently from such an instrument.

In some embodiments, excitation light can be steered through just a portion of a laser diode array at a time, which would reduce the electric power consumption of a system. In such embodiments, driver circuit 120 may independently activate/deactivate a portion of laser diodes within light source 106 for excitation of a pixel. At least some power consumption are attributed to switching of logic gates within the chip, which may be reduced by reducing the frequency of excitation light pulses seen by a pixel on the chip. In one non-limiting example, instead of driving an entire array of laser diodes are normally driven with 10 mW of total output power, the power can be concentrated on half the array for half time, and vice versa. This reduces the toggle frequency of logic gates in the pixel by a factor of two and as a result every pixel receives half the number of light pulses, but have twice the power and the same average power. It should be appreciated that other variations of differentially driving portions of a laser diode array may also be used.

### Exemplary Sensor Chip for Use with a Sequencing System

A cross-sectional schematic of integrated device or sensor chip 101 illustrating a row of pixels 112 is shown in FIG. 7. Integrated device 101 may include coupling region 201, routing region 202, and pixel region 203. Pixel region 203 may include a plurality of pixels 112 having sample wells 108 positioned on a surface at a location separate from coupling region 201, which is where excitation light (shown as the dashed arrow) couples to integrated device 101. Sample wells 108 may be formed through metal layer(s) 116. One pixel 112, illustrated by the dotted rectangle, is a region of integrated device 101 that includes a sample well 108 and photodetector region having one or more photodetectors 110.

FIG. 7 illustrates the path of excitation (shown in dashed lines) by coupling a beam of excitation light to coupling region 201 and to sample wells 108. The row of sample wells 108 shown in FIG. 7 may be positioned to optically couple with waveguide 220. Excitation light may illuminate a sample located within a sample well. The sample may reach an excited state in response to being illuminated by the excitation light. When a sample is in an excited state, the sample may emit emission light, which may be detected by one or more photodetectors associated with the sample well. FIG. 7 schematically illustrates the path of emission light (shown as the solid line) from a sample well 108 to photodetector(s) 110 of pixel 112. The photodetector(s) 110 of pixel 112 may be configured and positioned to detect emission light from sample well 108. Examples of suitable photodetectors are described in U.S. patent application Ser. No. 14/821,656, filed Aug. 7, 2015, titled “INTEGRATED DEVICE FOR TEMPORAL BINNING OF RECEIVED PHOTONS,” which is incorporated by reference herein in its entirety. Additional examples of suitable photodetectors are described in U.S. patent application Ser. No. 15/852,571, filed Dec. 22, 2017, titled “INTEGRATED PHOTODETECTOR WITH DIRECT BINNING PIXEL,” which is incorporated herein by reference in its entirety. For an individual pixel 112, a sample well 108 and its respective photodetector(s) 110 may be aligned along a common axis (along the y-direction shown in FIG. 7). In this manner, the photodetector(s) may overlap with the sample well within a pixel 112.

The directionality of the emission light from a sample well 108 may depend on the positioning of the sample in the sample well 108 relative to metal layer(s) 116 because metal layer(s) 116 may act to reflect emission light. In this manner, a distance between metal layer(s) 116 and a fluorescent marker positioned in a sample well 108 may impact the efficiency of photodetector(s) 110, that are in the same pixel as the sample well, to detect the light emitted by the fluorescent marker. The distance between metal layer(s) 116 and the bottom surface of a sample well 106, which is proximate to where a sample may be positioned during operation, may be in the range of 100 nm to 500 nm, or any value or range of values in that range. In some embodiments the distance between metal layer(s) 116 and the bottom surface of a sample well 108 is approximately 300 nm.

The distance between the sample and the photodetector(s) may also impact efficiency in detecting emission light. By decreasing the distance light has to travel between the sample and the photodetector(s), detection efficiency of emission light may be improved. In addition, smaller distances between the sample and the photodetector(s) may allow for pixels that occupy a smaller area footprint of the integrated device, which can allow for a higher number of pixels to be included in the integrated device. The distance between the bottom surface of a sample well 108 and photodetector(s) may be in the range of 1 μm to 15 μm, or any value or range of values in that range.

Photonic structure(s) 230 may be positioned between sample wells 108 and photodetectors 110 and configured to reduce or prevent excitation light from reaching photodetectors 110, which may otherwise contribute to signal noise in detecting emission light. As shown in FIG. 7, the one or more photonic structures 230 may be positioned between waveguide 220 and photodetectors 110. Photonic structure(s) 230 may include one or more optical rejection photonic structures including a spectral filter, a polarization filter, and a spatial filter. Photonic structure(s) 230 may be positioned to align with individual sample wells 108 and their respective photodetector(s) 110 along a common axis. Metal layers 240, which may act as a circuitry for integrated device 101, may also act as a spatial filter, in accordance with some embodiments. In such embodiments, one or more metal layers 240 may be positioned to block some or all excitation light from reaching photodetector(s) 110.

Coupling region 201 may include one or more optical components configured to couple excitation light from an external excitation source. Coupling region 201 may include grating coupler 216 positioned to receive some or all of a beam of excitation light. Examples of suitable grating couplers are described in U.S. patent application Ser. No. 15/844,403, filed Dec. 15, 2017, titled “OPTICAL COUPLER AND WAVEGUIDE SYSTEM,” which is incorporated by reference herein in its entirety. Grating coupler 216 may couple excitation light to waveguide 220, which may be configured to propagate excitation light to the proximity of one or more sample wells 108. Alternatively, coupling region 201 may comprise other well-known structures for coupling light into a waveguide.

Components located off of the integrated device may be used to position and align the excitation source 106 to the integrated device. Such components may include optical components including lenses, mirrors, prisms, windows, apertures, attenuators, and/or optical fibers. Additional mechanical components may be included in the instrument to allow for control of one or more alignment components. Such mechanical components may include actuators, stepper motors, and/or knobs. Examples of suitable excitation sources and alignment mechanisms are described in U.S. patent application Ser. No. 15/161,088, filed May 20, 2016, titled “PULSED LASER AND SYSTEM,” which is incorporated by reference herein in its entirety. Another example of a beam-steering module is described in U.S. patent application Ser. No. 15/842,720, filed Dec. 14, 2017, titled “COMPACT BEAM SHAPING AND STEERING ASSEMBLY,” which is incorporated herein by reference in its entirety.

A sample to be analyzed may be introduced into sample well 108 of pixel 112. The sample may be a biological sample or any other suitable sample, such as a chemical sample. The sample may include multiple molecules and the sample well may be configured to isolate a single molecule. In some instances, the dimensions of the sample well may act to confine a single molecule within the sample well, allowing measurements to be performed on the single molecule. Excitation light may be delivered into the sample well 108, so as to excite the sample or at least one fluorescent marker attached to the sample or otherwise associated with the sample while it is within an illumination area within the sample well 108.

In operation, parallel analyses of samples within the sample wells are carried out by exciting some or all of the samples within the wells using excitation light and detecting signals from sample emission with the photodetectors. Emission light from a sample may be detected by a corresponding photodetector and converted to at least one electrical signal. The electrical signals may be transmitted along conducting lines (e.g., metal layers 240) in the circuitry of the integrated device, which may be connected to an instrument interfaced with the integrated device. The electrical signals may be subsequently processed and/or analyzed. Processing or analyzing of electrical signals may occur on a suitable computing device either located on or off the instrument.

Instrument 180 may include a user interface for controlling operation of instrument 180 and/or integrated device 101. The user interface may be configured to allow a user to input information into the instrument, such as commands and/or settings used to control the functioning of the instrument. In some embodiments, the user interface may include buttons, switches, dials, and a microphone for voice commands. The user interface may allow a user to receive feedback on the performance of the instrument and/or integrated device, such as proper alignment and/or information obtained by readout signals from the photodetectors on the integrated device. In some embodiments, the user interface may provide feedback using a speaker to provide audible feedback. In some embodiments, the user interface may include indicator lights and/or a display screen for providing visual feedback to a user.

In some embodiments, instrument 180 may include a computer interface configured to connect with a computing device. Computer interface may be a USB interface, a FireWire interface, or any other suitable computer interface. Computing device may be any general purpose computer, such as a laptop or desktop computer. In some embodiments, computing device may be a server (e.g., cloud-based server) accessible over a wireless network via a suitable computer interface. The computer interface may facilitate communication of information between instrument 180 and the computing device. Input information for controlling and/or configuring the instrument 180 may be provided to the computing device and transmitted to instrument 180 via the computer interface. Output information generated by instrument 180 may be received by the computing device via the computer interface. Output information may include feedback about performance of instrument 180, performance of integrated device 112, and/or data generated from the readout signals of photodetector 110.

In some embodiments, instrument 180 may include a processing device configured to analyze data received from one or more photodetectors of integrated device 101 and/or transmit control signals to excitation source(s) 106. In some embodiments, the processing device may comprise a general purpose processor, a specially-adapted processor (e.g., a central processing unit (CPU) such as one or more microprocessor or microcontroller cores, a field-programmable gate array (FPGA), an application-specific integrated circuit (ASIC), a custom integrated circuit, a digital signal processor (DSP), or a combination thereof.) In some embodiments, the processing of data from one or more photodetectors may be performed by both a processing device of instrument 180 and an external computing device. In other embodiments, an external computing device may be omitted and processing of data from one or more photodetectors may be performed solely by a processing device of integrated device 101.

Having thus described several aspects of at least one embodiment of this invention, it is to be appreciated that various alterations, modifications, and improvements will readily occur to those skilled in the art. For example, while a system for molecule sequencing as described as an embodiment using the optical pulse stretchers disclosed herein, it should be appreciated that aspects of the present application are not limited to pulse stretcher for use in molecule sequencing, or any particular application. While discrete optical components are illustrated for the single etalon pulse stretcher in FIG. 1 and for the multiple loop pulse stretchers in FIGS. 4 and 5, it should be appreciated that any suitable construction may be used to form a pulse stretcher in accordance with the present disclosure. For example, while some optical path in FIGS. 1, 4 and 5 are shown as through free space, it is not a requirement as one or more components of an optical pulse stretcher may be constructed from a monolithic block. In some embodiments the optical pulse stretcher may be free of optical path in free space to provide a compact size. For example, the optical pulse stretcher 400 may comprise a plurality of prisms glued together.

Such alterations, modifications, and improvements are intended to be part of this disclosure, and are intended to be within the spirit and scope of the invention. Further, though advantages of the present invention are indicated, it should be appreciated that not every embodiment of the technology described herein will include every described advantage. Some embodiments may not implement any features described as advantageous herein and in some instances one or more of the described features may be implemented to achieve further embodiments. Accordingly, the foregoing description and drawings are by way of example only.

Various aspects of the technology may be used alone, in combination, or in a variety of arrangements not specifically discussed in the embodiments described in the foregoing and is therefore not limited in its application to the details and arrangement of components set forth in the foregoing description or illustrated in the drawings. For example, while in some examples a light source for a sequencing system are described, it should be appreciated that aspects of the optical pulse stretcher according to the present application are not limited to a sequencing application and may be used in any suitable light source to provide pulsed light signals. Aspects described in one embodiment may be combined in any manner with aspects described in other embodiments.

Also, aspects of the technology may be embodied as a method, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Such alterations, modifications, and improvements are intended to be part of this disclosure, and are intended to be within the spirit and scope of the invention. Further, though advantages of the present invention are indicated, it should be appreciated that not every embodiment of the invention will include every described advantage. Some embodiments may not implement any features described as advantageous herein and in some instances. Accordingly, the foregoing description and drawings are by way of example only.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

1. An optical pulse stretcher, comprising:
an input beam splitter configured to receive a pulsed light signal along a first direction and to provide a stretched light signal along a second direction; and
a first beam splitter and a cavity arranged in series with the input beam splitter along the second direction, wherein
a peak power of the stretched light signal is lower than a peak power of the pulsed light signal.

2. The optical pulse stretcher of claim 1, wherein the input beam splitter is a polarizing beam splitter, and the optical pulse stretcher further comprises:
a quarter-wave plate disposed between the polarizing beam splitter and the first beam splitter.

3. The optical pulse stretcher of claim 2, wherein the first beam splitter is configured to reflect a portion of an incident light signal from the polarizing beam splitter that passes through the quarter-wave plate along the second direction, and to transmit a portion of the incident light signal through the cavity.

4. The optical pulse stretcher of claim 1, wherein the cavity comprises a delay path and a mirror.

5. The optical pulse stretcher of claim 1, wherein the stretched light signal has a higher number of pulses per second than the pulsed light signal.

6. The optical pulse stretcher of claim 1, wherein a time duration of a pulse in the pulsed light signal is less than 100 ps, and
pulses in the stretched light signal form a ring-down envelope that has an attenuation in power of at least 30 dB within a time duration of 500 ps.

7. The optical pulse stretcher of claim 4, further comprising a second beam splitter between the first beam splitter and the delay path.

8. The optical pulse stretcher of claim 7, wherein the first beam splitter comprises a first semi-reflective surface of a plate, and the second beam splitter comprises a second semi-reflective surface of the plate that is opposite the first semi-reflective surface.

9. The optical pulse stretcher of claim 1, wherein the first beam splitter has a reflectance of between 20% and 50%.

10. The optical pulse stretcher of claim 7, wherein the first beam splitter has a reflectance of between 20% and 50%, and wherein the second beam splitter has a reflectance of between 20% and 50%.

11. The optical pulse stretcher of claim 7, wherein the first beam splitter and the second beam splitter is spaced such that it takes a first time duration for light to travel from the first beam splitter to the second beam splitter, and
the second beam splitter and the mirror is spaced such that it takes a second time duration for light to travel a round-trip between the second beam splitter and the mirror, wherein
a ratio between the first time duration to the second time duration is between ¼ and ½.

12. An optical device for stretching a pulsed light signal, comprising:
a first beam splitter configured to receive the pulsed light signal and to produce a first split signal and a second split signal;
a second beam splitter configured to receive the first and second split signals and to produce a third split signal and a fourth split signal;
a delay component disposed in an optical path between the first and second beam splitters and configured to delay a relative timing between the first and second split signals at the second beam splitter; and
a third beam splitter configured to receive the third and fourth split signals and produce a stretched light signal that is a stretched version of the pulsed light signal, wherein
a peak power of the stretched light signal is lower than a peak power of the pulsed light signal.

13. The optical device of claim 12, wherein the delay component is a first delay component, and the optical device further comprises a second delay component disposed in an optical path between the second and third beam splitters and configured to delay a relative timing between the third and fourth split signals at the third beam splitter.

14. The optical device of claim 12, wherein the stretched light signal has a higher number of pulses per second than the pulsed light signal.

15. The optical device of claim 12, wherein the stretched light signal exits the third beam splitter along a first direction, and the third beam splitter is further configured to produce a fifth split signal that exits along a second direction different from the first direction, and
the optical device further comprises:
a polarizing beam splitter configured to receive the fifth split signal and the stretched light signal and to produce a combined output light signal at an output optical path;
a first half-wave plate disposed in an optical path between the third beam splitter and the polarizing beam splitter and configured to rotate a polarization angle of the stretched light signal.

16. The optical device of claim 15, further comprising a second half-wave plate disposed in the output optical path of the polarizing beam splitter.

17. The optical device of claim 12, wherein the delay component is a glass plate having a thickness of between 5 and 50 mm along the optical path between the first and second beam splitters.

18. A system comprising:
a light source configured to illuminate a plurality of sample wells, the light source comprising:
a laser configured to produce a pulsed light signal; and
a pulse stretcher configured to receive the pulsed light signal, and to produce a stretched light signal for exciting a plurality of samples within the plurality of sample wells, wherein
a peak power of the stretched light signal is lower than a peak power of the pulsed light signal.

19. The system of claim 18, wherein the pulse stretcher comprises:
a polarizing beam splitter configured to receive the pulsed light signal along a first direction and to provide the stretched light signal along a second direction;
a quarter-wave plate, a first beam splitter, and a cavity arranged in series with the polarizing beam splitter along the second direction.

20. The system of claim 19, wherein the first beam splitter is configured to reflect a portion of an incident light signal from the polarizing beam splitter that passes through the quarter-wave plate along the second direction, and to transmit a portion of the incident light signal through the cavity, and
the cavity comprises a delay path and a mirror.

21. The system of claim 18, wherein the pulse stretcher comprises:
a first beam splitter configured to receive the pulsed light signal and to produce a first split signal and a second split signal;
a second beam splitter configured to receive the first and second split signals and to produce a third split signal and a fourth split signal;
a delay component disposed in an optical path between the first and second beam splitters and configured to delay a relative timing between the first and second split signals at the second beam splitter; and
a third beam splitter configured to receive the third and fourth split signals and produce the stretched light signal.
